(19) United States
(12) Patent Application Publication
(10) Pub. No.: US 2013/0276865 A1
(43) Pub. Date: Oct. 24, 2013

(54) SAW-TOOTH SHAPED SOLAR MODULE

(71) Applicant: PRISM SOLAR TECHNOLOGIES INCORPORATED, Highland, NY (US)

(72) Inventors: Eric D. Aspnes, Tucson, AZ (US); Paul S. Hauser, Tucson, AZ (US)

(21) Appl. No.: 13/865,805

(22) Filed: Apr. 18, 2013

Related U.S. Application Data
(63) Continuation-in-part of application No. 13/743,122, filed on Jan. 16, 2013.
Application No. 13/743,122 is a continuation-in-part of application No. 13/682,119, filed on Nov. 20, 2012.
Application No. 13/682,119 is a continuation-in-part of application No. 13/675,855, filed on Nov. 13, 2012.
(60) Provisional application No. 61/637,178, filed on Apr. 23, 2012.
(60) Provisional application No. 61/637,147, filed on Apr. 23, 2012.

(51) Int. Cl. H01L 31/052

(52) U.S. Cl. CPC H01L 31/0525
USPC 136/246

(57) ABSTRACT

A photovoltaic module, configured for inclined (with respect to the horizontal surface) installation at a chosen latitude as part of rows of such photovoltaic modules, is complemented with a diffractive element that is configured to form a combination in which a gap between neighboring rows is bridged by the diffractive element to diffract sunlight incident onto so installed diffractive element towards the photovoltaic module. The photovoltaic module and the diffractive elements can be connected to one another in a turnable fashion, for example through hinge, to enable electrical power generation that is substantially time-invariable throughout a portion of a year. Photovoltaic module optionally includes internal holographically-defined diffraction gratings and/or bifacial photovoltaic cells.

### CROSS-REFERENCE TO RELATED APPLICATIONS

The present patent application claims benefit of and priority from the U.S. Provisional Patent Applications Nos. 61/637,178 filed on Apr. 23, 2012 and titled “Saw-Tooth Shaped Solar Panel With Holographic Reflector” and 61/637,147 filed on Apr. 23, 2012 and titled “Holographic Mirror for Between Rows In a Solar Array”. Disclosure of each of these provisional patent applications is incorporated herein in its entirety by reference, for all purposes.

The present patent application is also a continuation-in-part of the co-pending U.S. patent application Ser. No. 13/743,122 filed on Jan. 16, 2013 and titled “Bussing for PV-Module with Unequal-Efficiency Bi-Facial PV-Cells”; Ser. No. 13/682,119 filed on Nov. 20, 2012 and titled “Encapsulated Solar Energy Concentrator”; and Ser. No. 13/675,855 filed Nov. 13, 2012 and titled “Flexible Photovoltaic Module”. The disclosure of each of these patent applications is incorporated herein by reference in its entirety.

### TECHNICAL FIELD

The present invention relates to system and method for fabrication of a PV-cell-based solar-power concentrator and, more particularly, to system and method for passive compensation of less than optimal solar-power collection caused by predetermined positioning a PV cell in a concentrator.

### BACKGROUND

Solar energy will satisfy an important part of future energy needs. While the need in solar energy output has grown dramatically in recent years, the total output from all solar installations worldwide still remains around 7 GW, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost per unit of efficiency of energy conversion. The main-stream technologies that are being explored to improve the cost-per-kilowatt of solar power are directed to (i) improving the efficiency of a solar cell that comprises solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, it remains disadvantageous for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted in coordination with the surface of the PV cell. In most of the existing systems used for concentration of solar radiation that employ holographic diffractive gratings, the manner in which the gratings are disposed in relation to a given PV cell is of substantial importance, as it influences the efficiency of sun-light collection and redirection of the collected light towards the PV cell.

### SUMMARY

Embodiments of the invention provide a solar-energy collecting module that includes a first photovoltaic (PV) module defining a first PV cell having a first photo-voltaically operable surface and disposed at a first angle (with respect to a horizontal surface) that is defined by a geographical latitude of position of the first PV module. The module also includes a diffractive element disposed in proximity to the first PV module at a second angle (with respect to the horizontal surface). The second angle chosen such as to ensure that sunlight incident on and diffracted in reflection from the diffractive element is incident onto a sunlight collecting surface of the first PV cell. In a related embodiment, the first PV module includes at least two first strings each including unequal efficiency bifacial PV cells (UEB cells) electrically connected in series such that each of the cells in a first string has one side with a first conversion efficiency and an opposite side with a second conversion efficiency, the second conversion efficiency being smaller than the first conversion efficiency, wherein all UEB cells in a first string having corresponding sides with the first conversion efficiency face in a first direction. In such related embodiment the first PB module additionally includes at least two second strings each including the UEB cells electrically connected in series such that corresponding sides of the UEB cells with the second conversion efficiency face in the first direction. In a specific embodiment, at least one of the at least two first strings and at least one of the at least two second strings are electrically connected in parallel.

The first PV module and the diffractive element may be hingedly connected along a line forming portions of both a perimeter of the PV module and a perimeter of the diffractive element to define a variable dihedral angle between a plane of the PV module and a plane of the diffractive element. In a specific implementation, the solar-collecting module enables a power output, in response to sunlight incident thereon, that includes a substantially time-invariable power output.

Embodiments of the present invention provide a first PV module defining a first PV cell having a first photo-voltaically operable surface and disposed at a first angle (with respect to a horizontal surface) that is defined by a geographical latitude of position of the first PV module; and a diffractive element disposed in proximity to said first PV module to form a dihedral angle with the first PV module to ensure that sunlight incident on and diffracted in reflection from the diffractive element is incident onto a sunlight collecting surface of the first PV cell. Such first PV module includes (i) a bifacial PV cell having first and second operational surfaces; and (ii) encapsulating materials disposed to cover said first and second surfaces. The first PV module additionally includes (iii) first and second optical substrates positioned to sandwich said bifacial PV cell with encapsulating materials disposed thereon, such that each of the first and second optical substrates are in optical contact with a corresponding encapsulating material; and (iv) an internal-to-the PV-module holographic diffraction grating element configured to operate in transmission and adjacent to and substantially coplanar with the bifacial PV cell between the first and second covers. This holographic diffraction grating element is configured to redirect light, incident thereon through the first cover at a substantially normal incidence, along a path defined by total internal reflection in the second cover and ending at the second operational surface.

### BRIEF DESCRIPTION OF THE DRAWINGS

The invention will be more fully understood by referring to the following Detailed Description in conjunction with the Drawings, of which:

FIG. 1 is a perspective of solar-energy collecting farm including multiple rows of spatially fixed photovoltaic (PV) modules.

FIG. 2 is a perspective view of the farm of FIG. 1, wherein the space separating immediately neighboring rows of PV modules are at partially bridges by diffractive elements according to an embodiment of the invention.

FIGS. 3A, 3B are schematic diagrams showing in side view embodiments of the invention.

FIG. 4 is a diagram illustrating the use of an encapsulating layer.

FIGS. 5A, 5B, 5C illustrate performance of a unit module of an embodiment of the invention optimized for operation at 32 degree latitude, 42 degree latitude, and 54 degree latitude of the northern hemisphere, in comparison with operational performance of related unit modules.

### DETAILED DESCRIPTION

As broadly used and described herein, the reference to a layer as being “carried” on or by a surface of an element refers to both a layer that is disposed directly on the surface of an element or a layer that is disposed on another coating, layer or layers that is/are, in turn disposed directly on the surface of the element.

PV panels, or modules, or individual cells in a solar-power harvesting farm are usually mounted at an angle with respect to a horizontal surface. Such angled mounting is caused by the need to maximize a projection area of the PV cell with respect to the sun to maximize the amount of solar power collected by the cell, and results in such positioning of the PV cell that an angle between the normal to the PV-cell's surface and a line connecting the PV cell and the sun is minimized. If and when it is possible to engage an active tracking system that changes the orientation of the PV cell as the sun progresses across the sky, the dihedral angle between the sunlight-collecting surface of the PV cell and a local horizontal surface may be changed by the tracking system during the course of the day, and the neighboring cells could be mounted and reoriented such as at no time there is any substantial “dead” space (i.e., the space not efficiently covered by a PV-cell surface) left between the panels. However, the use of the active tracking system is cost-prohibitive and/or impractical from the point of view of operational characteristics such as weight, for example, at least in the case of installation of the PV-modules on residential and commercial flat roofs that have a limit to their weight-carrying capacity.

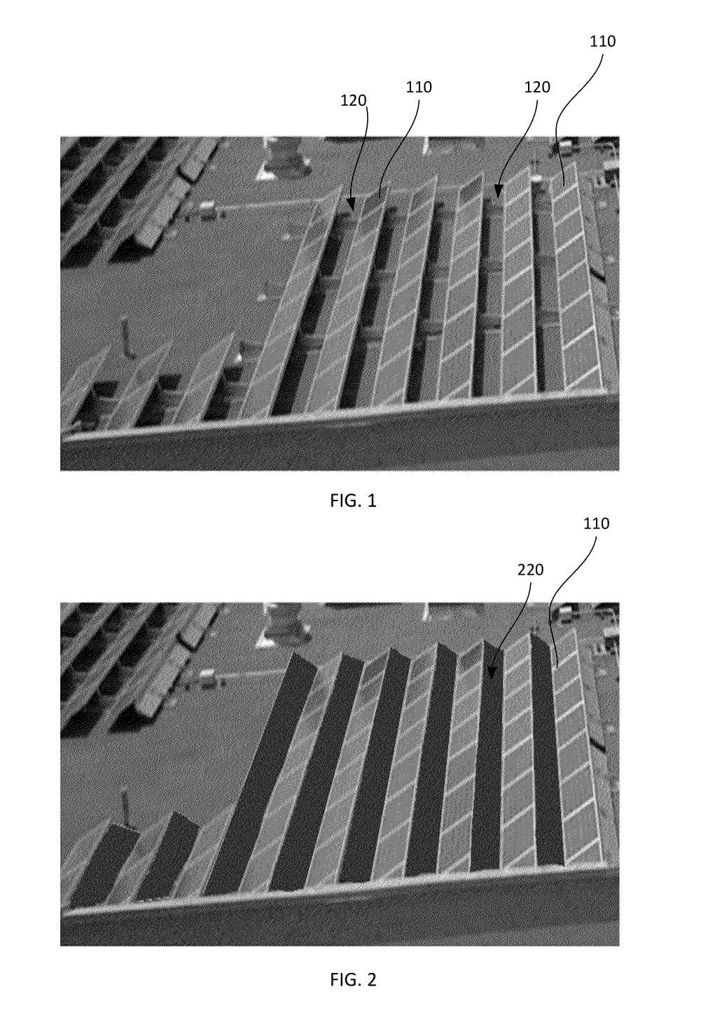

Accordingly, in this type of application, the spatial orientations of the PV-modules 110 of a solar-power collector are fixed (typically at angles close to the inclination of the sun at the equinox), as shown in FIG. 1. In this case, care should be taken to ensure that no portion of the solar module casts a shadow on any other electricity-generating portion of the solar module because the shading at least reduces the sunlight collection efficiency and, in some cases, can cause damage to the PV cells. The shading of a PV cell reduces the current produced by the cell. (As the voltage stays constant, the power generation by the shaded cell is also reduced.) The shading of one PV cell in a multi-cell module reduced the current of all PV cells strung in a series with the shaded PV cell to the level of current corresponding to the shaded PV cell. The power corresponding to the difference between the current value that should be produced by a non-shaded cell and the current value that such cell produces due to the shading of another PV cell in the module is converted into heat, heating the cell(s) and reducing its/their lifetime.

To ensure that no shading occurs, the individual PV modules 110 are spatially separated to define the separating space 120, which from the point of view of solar-power harvesting is the space substantially unused. While the shading effects may be particularly pronounced (in the northern hemisphere) at or around the winter solstice (at which time the sun's position in the sky has the lowest inclination), elimination of shading effects and optimal use of the space separating the individual spatially-fixed PV modules is advantageous at any time of exploitation of the PV module(s). There remains a need, therefore, in a solar-power collector obviating the operational shortcomings possessed by PV modules the spatial orientation of which is fixed on a flat surface.

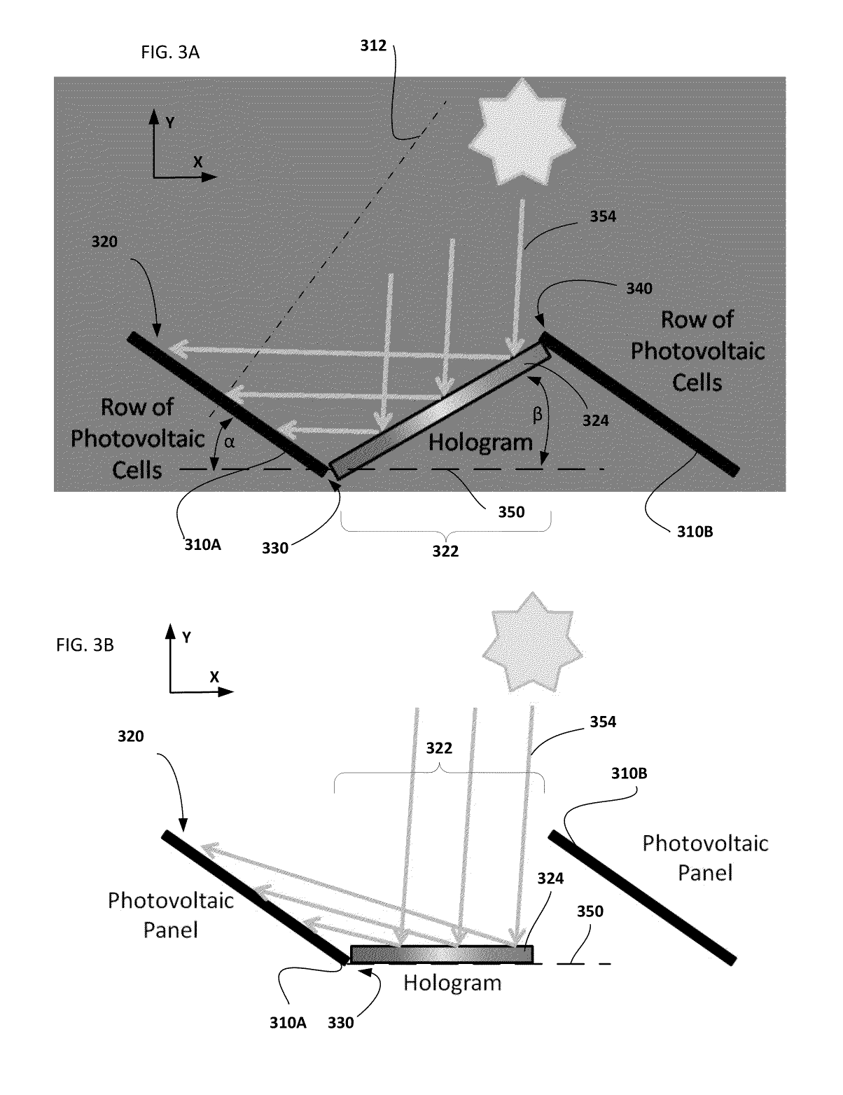

According to an idea of the invention, a diffractive element (such as an element carrying or containing a diffraction grating, for example) is disposed in the “separating” or “dead” space (indicated as space 120 in FIG. 1), which is defined between the individual not-casting-shadow-on-one-another PV modules spatially fixed on a horizontal surface at predetermined angles, to diffract sunlight incident onto the “separating” space towards a sunlight-collecting surface of the immediately adjacent PV modules. This is schematically illustrated by a solar-power collecting structure of FIG. 2 which, in comparison with that of FIG. 1, contains diffractive elements 220 between the PV modules 110. Additional details of specific embodiments of the invention are illustrated in FIGS. 3A, 3B. As further discussed below, the use of a diffractive element positioned to gap the space between immediately adjacent PV modules is advantageous as compared with the use of a simple specular reflector (such as a mirror, for example) similarly positioned to redirect a portion of incident light towards the nearby PV module.

This invention is described in preferred embodiments in the following description with reference to the Figures, in which like numbers represent the same or similar elements. Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

The described features, structures, or characteristics of the invention may be combined in any suitable manner in one or more embodiments. In the following description, numerous specific details are recited to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

FIG. 3A shows schematically, in side view, rows 310A, 310B of individual PV cells, shown in side view, is mounted at such a predetermined angle α with respect to the horizontal surface 350 that a normal 312 (defined with respect to a sunlight collecting surface 320 of a PV cell) is directed substantially towards the sun during the course of the day. The extent of each of the PV cells 110 in xy-plane is denoted as A. The space 322 between the immediately neighboring rows 310A, 310B of PV cells is covered by a diffractive element 324 that extends between the immediately neighboring edges 330, 340 of the rows 310A, 310B. The extent of the diffractive element 324 in the xy-plane is denoted as β. While in the embodiment of FIG. 3 the diffractive element 324 is shown to substantially fully bridge the gap 322 between the edges 330, 340, generally such diffractive element may cover at least a portion of space separating the rows 310A, 310B of PV cells. The dihedral angle β that a surface of the diffractive element 324 forms with a local horizontal surface 350 is generally defined by an average angle of incidence of sunlight 354 onto the diffractive element 324, the angle of inclination a of the row 310A, and the resulting condition of diffraction of light that is satisfied by the design of the grating of the element 324 to ensure the diffraction of sunlight incident onto the grating towards the rows 310A. The average angle of incident of sunlight is latitude-specific.

FIG. 3B shows an alternatively structured combination of the rows 110 of PV modules with a diffractive element 324 that is positioned in a plane substantially parallel to the horizontal surface 350 such as to bridge the gap 322 between the immediately adjacent rows 110. The reflective diffraction grating contained in the diffractive element 324 is appropriately structured to ensure that sunlight 354 incident into the gap 322 is diffracted towards the immediately adjacent row 110 of PV cells.

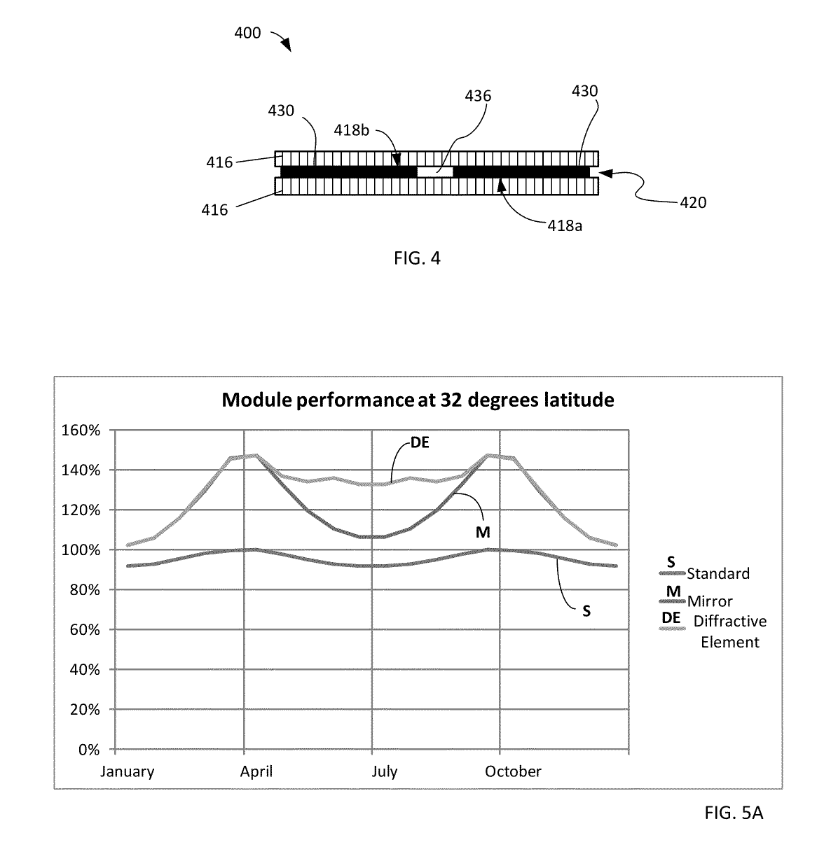

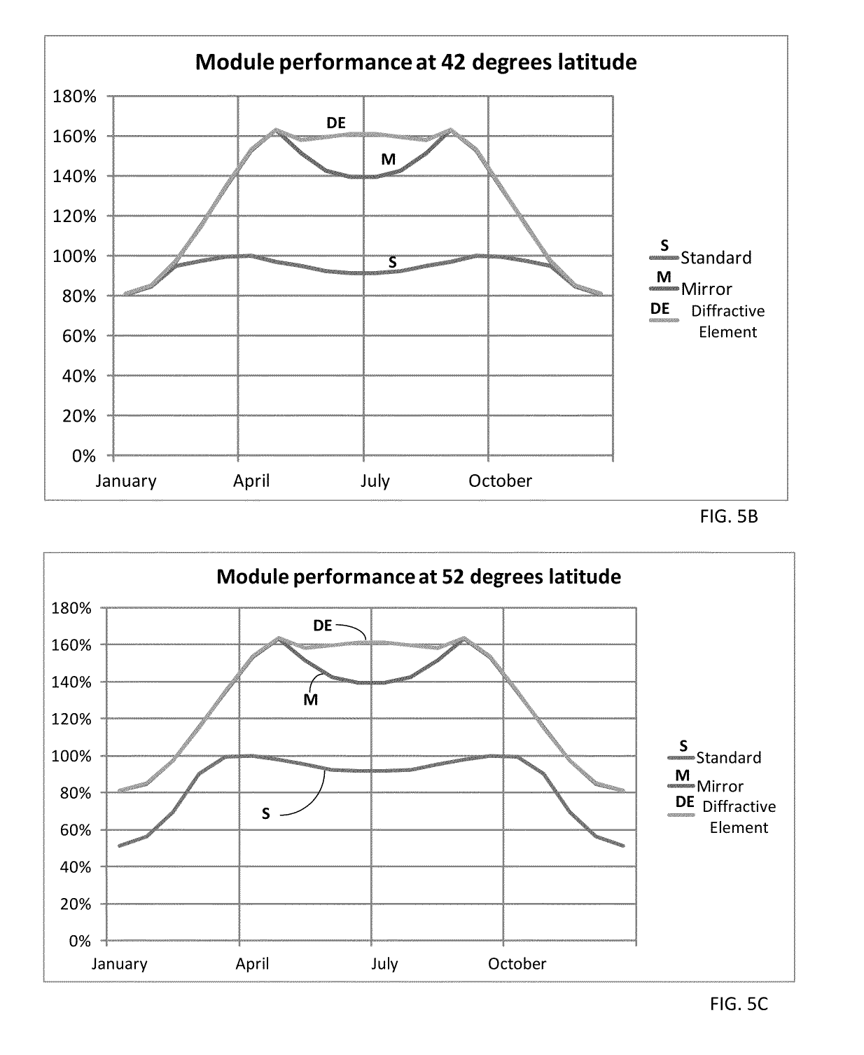

While in both FIG. 3A and FIG. 3B the diffractive element 324 is labeled as “hologram”, it is done so only for the purposes of providing an example. It is appreciated that the diffractive element 324, in general, includes a diffraction grating structured to operate in reflection and fabricated either as a conventional diffraction grating having a relief surface (for example, rulings in the substrate material) or as a holographically-defined diffraction grating. Both the diffractive element 324 and the PV modules 310A, 310B may be structured according to the teachings of the U.S. patent application Ser. No. 13/675,855. Such structure includes the use of bi-facial PV cells, the cooperation of multiple PV cells within a PV module (as shown, for example, in FIGS. 4A, 4B, 5A, 5B of U.S. Ser. No. 13/675,855), and appropriately-configured electrical interconnections between and among the PV as described in the above-mentioned patent application.

The combination of the elements 310A and 324, cooperated in saw-tooth like patterns according to FIG. 3A or FIG. 3B (or, alternatively, a combination of the element 310B with a diffractive element disposed to diffract the light onto the surface of the element 210B) is referred to herein as a unit module.

In one embodiment of the invention, the diffractive element 324 is structured to optimize the performance of a unit module installed, in a given geographic locale, according to latitude. Table 1 shows data describing three examples of a unit module, respectively optimized for operation at the latitudes of approximately 32 degrees (Tucson, Ariz.), approximately 42 degrees (New York, N.Y.), and approximately 52 degrees (London, England). In further reference to FIG. 3A, for example, several of such unit modules connected to one another along the z- and x-directions of FIG. 3A, for example, form a bigger module shown in FIG. 2, in which the number of PV cells per row 110 and the number of rows is also indicated in Table 1.

TABLE 1

| | 32 degrees latitude | | 42 degrees latitude | | 52 degrees latitude | |
|---|---|---|---|---|---|---|
| A | 166 mm (156 mm | | 166 mm (156 mm | | 166 mm (156 mm | |
| | of silicon and 2.5 | | of silicon and 2.5 | | of silicon and 2.5 | |
| | mm of structural | | mm of structural | | mm of structural | |
| | material.) | | material.) | | material.) | |
| α | 32 | degrees | 42 | degrees | 52 | degrees |
| B | 170 | mm | 215 | mm | 253 | mm |
| β | 29 | degrees | 29 | degrees | 29 | degrees |

| | | | |
|---|---|---|---|
| Module | 948 mm × 1124 mm | 948 mm × 911 mm | 948 mm × 952 mm |
| foot- | | | |
| print | | | |
| PV cells | 6 | 6 | 6 |
| per row | | | |
| Rows | 4 | 3 | 3 |
| per | | | |
| module | | | |

Table 2 provides an example of an aluminum-coated ruled blazed grating for use in the embodiments of Table 1. The holographic embodiments of the diffractive element 324 are appropriately designed to have operational characteristics that are substantially identical to those of the gratings of Table 2.

TABLE 2
Embodiment of diffractive element 324
(aluminum -coated reflective grating)

| | 32 degrees latitude | | 42 degrees latitude | | 52 degrees latitude | |
|---|---|---|---|---|---|---|
| Period | 4 | micrometers | 4 | micrometers | 4 | micrometers |
| Blaze | 4 | degrees | 4 | degrees | 4 | degrees |
| angle | | | | | | |

As a result, the overall PV-system of the invention is structured to have a saw-tooth cross-section. In a related embodiment (not shown), for example, at least a portion of the diffractive element 220 of FIG. 2 includes a specular reflector, which is appropriately mounted to redirect sunlight incident onto the reflector.

In a related embodiment (not shown), individual angled-mounted PV modules and diffractive elements between those modules are combined (optionally, with the use of hinges) to form a holographic-gratings-containing and optionally foldable upon itself photovoltaic panel or system that includes multiple rows of photovoltaic cells. In one example, Yingli Solar 235 W polycrystalline solar panels and/or Yingli Solar 260 W monocrystalline solar panels can be used for this purpose (both of which panels contains 6 rows of 156 mm square solar cells). An overall solar-energy harvesting farm of an embodiment of the invention (such as that shown in FIG. 2) can be structured to include multiply-repeated combinations of a row of PV-modules and an associated row of diffractive elements.

At least one of the PV module or an individual cell and an associated diffractive element could be covered with a structural protective layer of glass or plastic (or other transparent material). Alternatively or in addition, the PV module and/or the diffractive element complementing the PV module may include an encapsulating layer. Because individual PV-cells are thin and delicate, and thereby subject to breakage or other damage, for example by scratching, chemical etching, or the like, PV-cells are optionally encapsulated with an optically and IR clear adhesive such as ethyl vinyl acetate (“EVA”) or silicone. In certain embodiments, such as san embodiment 400, of the PV module 110, shown in FIG. 4, an encapsulant 416 is provided in the form of two sheets of EVA that are laminated to sides 418a, 418b of the PV-module layer 420 (for example, before the resulting assembly is laminated to glass, not shown, although the exact sequence of steps in the lamination process can vary). The PV module layer 420, as shown, contains two PV cells 430 separated by a gap 436. In the case of a monofacial PV cell, instead of one glass layer, a backsheet or protective sheet made of some polymeric material (e.g., polyethylene terephthalate, or PET) is optionally provided to which the PV cells are first adhered before being laminated to front side glass (not shown) with an encapsulant layer. In some conventional embodiments, a backsheet is provided with encapsulant pre-deposited. In some conventional embodiments, glass is used as a backsheet, even for monofacial cells. In a related embodiment, a single encapsulant layer may be used in juxtaposition with one side of the PV-module. Optionally, a structural frame is attached around the sides of a standard PV panel or, alternatively, the PV panel could be frameless.

The operational performance of the unit modules of embodiments of the invention that incorporate diffractive elements structured according to the parameters in Tables 1 and 2 is further illustrated in FIGS. 5A, 5B, and 5C. For comparison purposes, all three modeled unit modules utilize PV cells and diffractive elements of the same type and area. The operational performance is defined as a time-of-the-year dependent ratio of power generated by a unit module including a PV cell and a diffractive element (curves DE) or power generated by a unit module including a PV cell and a aluminized mirror (curves M) and maximum power generated by a “standard” unit module (PV cell by itself, curves S). The latter value corresponds to 100% on each of FIGS. 5A, 5B, 5C. The “standard” unit module denotes a PV cell that is tilted, with respect to the horizontal surface and towards the south, at an angle approximately equal to the immediate latitude angle. (Installing solar modules tilted at an angle matching the latitude of installation is a common method of solar module mounting as it maximizes the overall power output of the solar module throughout the year.) The curves labeled with “M” describe operational performance of a unit module in which a metalized mirror is added to the PV cell in place of a diffractive element 324 of FIG. 3A to reflect incident light towards the PV cell and such that the mirror is not shaded by the PV cell. The curves DE describe operational performance of the unit module structured according to the diagram of FIG. 3A.

As evidenced by comparison between the curves DE and M of FIGS. 5A through 5C, the use of a diffractive element in an embodiment of the invention enables a significant increase in power output throughout the year as compared to both the use of a module employing only the rows PV cells (as in FIG. 1) and a module employing the rows of PV cells the gaps between which are bridged with a simple specular reflector.

It is recognized that an embodiment of the invention provides operational advantage over PV systems of related art. In particular, as evidenced by FIGS. 5A, 5B, 5C, the use of a diffractive element 324 at a dihedral angle with respect to a PV that is inclined to the horizontal surface enables a substantially time-invariable power output (labeled as 520) during at least half-a-year (April-October, in case of the northern hemisphere). Specifically, the embodiment of the invention generates a power output 520 that is substantially flat (as compared to the outputs generated by PV systems S and M of FIGS. 5A, 5B, 5C) due to the use of non-specularly reflecting optical element 324.

The data representing the operation of various modules in FIGS. 5A, 5B, and 5C were acquired with a multi-wavelength simulation, of a unit module including a 6-inch square PV cell, in Zemax optical modeling software and a diffractive element, with 8 million rays per data point, for 20 different days equally sampled throughout the year. The simulation model accounted at least for the angular performance of the diffractive element, the solar spectrum, the tabulated values of absorption of the solar light by the atmosphere, and for the spectral response of monocrystalline silicon of the PV cell.

It is appreciated that any of the elements 310A, 310B of FIGS. 3A, 3B may be structured, for example, according to the teachings of U.S. Ser. No. 13/682,119, the disclosure of each of which is incorporated herein by reference in its entirety. In this case, an embodiment of the invention may include a PV module including (i) an optionally bi-facial PV cell having a first photo-voltaically operable surface; (ii) a first encapsulant material covering said first photo-voltaically operable surface; (ii) an internal (to the PV module) holographic grating element adjacent to and substantially coplanar with the PV cell; (iii) a first optically transparent cover disposed in optical contact with the first encapsulant layer, and (iv) a backsheet adhered to the PV cell along a surface opposite to the first photo-voltaically operable surface. In such embodiment, the first optically transparent cover may extend over the holographic grating element, and be dimensioned to reflect light (that has been received by the internal holographic grating element through the first optically transparent cover at about normal incidence) along a path defined by total internal reflection in said first optically transparent cover and ending at the first photo-voltaically operable surface. The internal holographic grating element could be embedded in a second encapsulant material. For example, in reference to FIGS. 5 and 7 of U.S. Ser. No. 13/682,119 and, in particular to elements 420, 422, 430, 432, 436 of FIG. 5 and elements 324, 312 of FIG. 7, at least one of the PV modules 310A, 310B of FIG. 3 of the present application can include multiple PV cells alternating with internal-to-the-module holographic elements that redirect sunlight incident onto the PV module 310A, 310B within its boundaries but outside of a PV cell.

While specific values chosen for these embodiments are recited, it is to be understood that, within the scope of the invention, the values of all of parameters may vary over wide ranges to suit different applications. The invention should not be viewed as being limited to the disclosed embodiments. Envisioned claims may be directed to at least a system and/or method for fabrication of a holographic optical film preform, an article of manufacture produced with the use of such system and/or method, and a computer program product for use with a system and/or method of an embodiment of the invention.

1. A solar-energy collecting module comprising
a first photovoltaic (PV) module defining a first PV cell having a first photo-voltaically operable surface, the first PV module disposed at a first angle with respect to a horizontal surface, the first angle being defined by a geographical latitude of position of the first PV module; and
a diffractive element disposed in proximity to said first PV module at a second angle with respect to the horizontal surface, the second angle chosen to ensure that sunlight incident on and diffracted in reflection from the diffractive element is incident onto a sunlight collecting surface of the first PV cell.

2. A module according to claim 1, further comprising a second PV module disposed at a third angle with respect to the horizontal surface and separated from the first PV module such that a normal to the horizontal surface that passes through a point of the second PV module does not intersect the diffractive element inside a perimeter thereof.

3. A module according to claim 2, wherein the diffractive element bridges a gap between the first and second PV modules such as to substantially extend from an edge of the first PV module to an edge of the second PV module.

4. A module according to claim 2, wherein the second angle is such that each of a first foot-print of the first PV module and a second foot-print of the second PV module shares at least one common point with a foot-print of the diffractive element, each of said foot-prints of said devices defined by a normal projection of a corresponding device onto a horizontal surface.

5. A module according to claim 2, wherein to define a saw-tooth shaped cross section in a plane containing a first normal to a surface of the first PV module, a second normal to a surface of the second PV module, and a normal to a surface of the diffractive element.

6. A module according to claim 1, wherein the first PV module and the diffractive element are hingedly connected along a line forming portions of both a perimeter of the PV module and a perimeter of the diffractive element to define a variable dihedral angle between a plane of the PV module and a plane of the diffractive element.

7. A module according to claim 1 that enables a power output, in response to sunlight incident thereon, that includes a substantially time-invariable power output.

8. A module according to claim 1, disposed such that the first and second angles are substantially equal to the geographical latitude.

9. A solar-energy collecting module comprising
a first photovoltaic (PV) module defining a first PV cell having a first photo-voltaically operable surface, the first PV module disposed at a first angle with respect to a horizontal surface, the first angle being defined by a geographical latitude of position of the first PV module; and
a diffractive element disposed in proximity to said first PV module to form a dihedral angle with the first PV module to ensure that sunlight incident on and diffracted in reflection from the diffractive element is incident onto a sunlight collecting surface of the first PV cell,
wherein the first PV module contains:
at least two first strings each including unequal efficiency bifacial PV cells (UEB cells) electrically connected in series, each of the cells in a first string having one side with a first conversion efficiency and an opposite side with a second conversion efficiency, the second conversion efficiency being smaller than the first conversion efficiency, wherein all UEB cells in a first string having corresponding sides with the first conversion efficiency face in a first direction; and
at least two second strings each including the UEB cells electrically connected in series such that corresponding sides of the UEB cells with the second conversion efficiency face in the first direction;
wherein at least one of the at least two first strings and at least one of the at least two second strings are electrically connected in parallel.

10. A module according to claim 9, further comprising a second PV module disposed at a third angle with respect to the horizontal surface and separated from the first PV module such that a normal to the horizontal surface that passes through a point of the second PV module does not intersect the diffractive element inside a perimeter thereof.

11. A module according to claim 9, wherein the diffractive element bridges a gap between the first and second PV modules such as to substantially extend from an edge of the first PV module to an edge of the second PV module.

12. A module according to claim 9 that enables a power output, in response to sunlight incident thereon, that includes a substantially time-invariable power output.

13. A solar-energy collecting module comprising
a first photovoltaic (PV) module defining a first PV cell having a first photo-voltaically operable surface, the first PV module disposed at a first angle with respect to a horizontal surface, the first angle being defined by a geographical latitude of position of the first PV module; and
a diffractive element disposed in proximity to said first PV module to form a dihedral angle with the first PV module to ensure that sunlight incident on and diffracted in reflection from the diffractive element is incident onto a sunlight collecting surface of the first PV cell,
wherein the first PV module includes:
a bifacial PV cell having first and second operational surfaces;
encapsulating materials disposed to cover said first and second surfaces;
first and second optical substrates positioned to sandwich said bifacial PV cell with encapsulating materials disposed thereon, each of said first and second optical substrates being in optical contact with a corresponding encapsulating material; and
a holographic diffraction grating element configured to operate in transmission,
said holographic diffraction grating element being adjacent to and substantially coplanar with the PV cell between the first and second covers,
said holographic diffraction grating element configured to redirect light, incident thereon through the first cover at a substantially normal incidence, along a path defined by total internal reflection in the second cover and ending at the second operational surface.

14. A module according to claim 13, further comprising a second PV module disposed at a third angle with respect to the horizontal surface and separated from the first PV module such that a normal to the horizontal surface that passes through a point of the second PV module does not intersect the diffractive element inside a perimeter thereof.

15. A module according to claim 13, wherein the diffractive element bridges a gap between the first and second PV modules such as to substantially extend from an edge of the first PV module to an edge of the second PV module.

16. A module according to claim 13, wherein the first PV module and the diffractive element are hingedly connected along a line forming portions of both a perimeter of the PV module and a perimeter of the diffractive element to define a variable dihedral angle between a plane of the PV module and a plane of the diffractive element.

17. A module according to claim 13 that enables a power output, in response to sunlight incident thereon, that includes a substantially time-invariable power output.
